(19) United States
(12) Patent Application Publication
(10) Pub. No.: US 2003/0137352 A1
(43) Pub. Date: Jul. 24, 2003

(54) Variable gain amplifier circuitry in automatic gain control

(76) Inventors: Yong-sik Youn, Daejeon-city (KR); Min-hyung Cho, Daejeon-city (KR); Hye-ju Seo, Daejeon-city (KR); Jong-kee Kwon, Daejeon-city (KR); Kyung-soo Kim, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/329,272

(22) Filed: Dec. 24, 2002

(30) Foreign Application Priority Data
Dec. 27, 2001 (KR) 2001-85836

(51) Int. Cl. H03F 3/16; H03G 3/30

(52) U.S. Cl. 330/277; 330/278

(57) ABSTRACT

A variable gain amplifier (VGA) circuitry for implementing gain as a pseudo exponential function by using the linear area of metal oxide semiconductor field effect transistors (MOSFETs) is provided. The VGA circuitry includes a fixed resistor and a variable resistor, which is connected in serial to the fixed resistor and implemented by combining one or more MOSFETs operating in a linear area with different control voltages to each MOSFET. Although the MOSFET has no exponential characteristics, the VGA circuitry can easily implement a pseudo exponential function with a simple structure. Further, since a complex circuit for generating an exponential function is not necessary, power consumption thereof can be eliminated.

### BACKGROUND OF THE INVENTION

1. Field of the Invention

The present invention relates to a variable gain amplifier (VGA) in automatic gain control (AGC), and more particularly, to a VGA circuitry for implementing gain as a pseudo exponential function by using the linear region of a metal-oxide semiconductor field effect transistor (MOSFET).

2. Description of the Related Art

The amplitudes of signals are varied according to the distance and state between a transmitting terminal and a receiving terminal. In particular, signals in a radio system are varied more by various parameters, and a VGA to control the amplitudes of signals is necessary for signal processing.

In general, the VGA automatically controls gain in a feedback loop, and this is referred to as AGC. The gain of VGA is varied exponential-functionally with respect to a control voltage. This is the reason transient response and a settling time in an AGC feedback loop are guaranteed uniformly and decibel (dB) represented as a logarithmic function is used as a standard of gain, and thus a design is facilitated. FIG. 1 is a circuit diagram illustrating the characteristics of a bipolar junction transistor (BJT) and a MOSFET, respectively.

A BJT and a MOSFET are used in a typical semiconductor manufacturing process. As shown in Equation 1, an output current I_{c} of the BJT has the characteristics of an exponential function of an input voltage V_{BE}. On the other hand, as shown in Equation 2, output current I_{D} of the MOSFET has the characteristics of a square or linear function of a difference between an input voltage V_{GS} and a threshold voltage V_{T} according to an operating region.

$$\begin{matrix}{I}_{c} = α \cdot exp [ \frac{{V}_{BE}}{kT / q} ] & ( 1 ) \\ \begin{matrix}\begin{matrix}{I}_{D} = β \cdot {( {V}_{GS} - {V}_{T} )}^{2} , in saturation region \\ = 2 β \cdot ( {V}_{GS} - {V}_{T} ) \cdot {V}_{DS} , in linear region\end{matrix} & \end{matrix} & ( 2 )\end{matrix}$$

Thus, unlike the BJT having the characteristics of an exponential function, the MOSFET having the characteristics of a square or linear function has the difficulty in implementing an exponential function. Implementation of an exponential function can be achieved using a substrate BJT, which can be implemented by the MOSFET process itself. In such a case, the larger the dynamic range of VGA is, the more rapidly the power consumption increases due to the exponential-functionally varied current of the BJT.

### SUMMARY OF THE INVENTION

To solve the above problems, it is an object of the present invention to provide a VGA circuitry for implementing gain as a pseudo exponential function by using the linear area of a MOSFET.

It is another object of the present invention to provide the VGA circuitry, which is implemented simply and easily without additional power consumption.

Accordingly, to achieve the above object, according to one aspect of the present invention, there is provided a VGA circuitry. The VGA circuitry includes at least one fixed resistor which is composed of either a passive resistor (R) or a metal oxide semiconductor field effect transistor (MOSFET) having the equivalent resistance value (1/gm) at the source node, and one fixed resistor is used for a single signal or two and more fixed resistor are used for differential signal; and a variable resistor, which is connected in serial to the fixed resistor, composed of a plurality of MOSFETs which are connected in parallel with each other, operate in a linear region, and have the different control voltages at each gate node.

To achieve the above object, according to another aspect of the present invention, there is provided a VGA circuitry. The VGA circuitry includes at least one fixed resistor which is composed of either a passive resistor (R) or a metal oxide semiconductor field effect transistor (MOSFET) having the equivalent resistance value (1/gm) at the source node, and one fixed resistor is used for a single signal or two and more fixed resistor are used for differential signal; and a variable resistor, which is connected in serial to the fixed resistor, composed of a plurality of MOSFETs which are connected in parallel with each other, operate in a linear region, and have the different control voltages at each gate node; and at least one MOSFET operating in saturation region for signal amplification, which is one for single signal or two for differential signal, and connected directly with the fixed resistor or the variable resistor at the source or drain node of the saturation MOSFET.

### BRIEF DESCRIPTION OF THE DRAWINGS

The above object and advantages of the present invention will become more apparent by describing in detail preferred embodiments thereof with reference to the attached drawings in which:

FIG. 1 is an equivalent circuit diagrams illustrating the characteristics of a BJT and a MOSFET, respectively;

FIG. 2A illustrates a VGA circuitry comprised of a fixed resistor and a variable resistor according to the present invention;

FIG. 2B illustrates the characteristics of the VGA circuitry of FIG. 2A;

FIG. 3A illustrates a variable resistor composed of parallel-connected MOSFETs with different control voltages and the equivalent model symbol;

FIG. 3B illustrates a VGA circuitry having a pseudo exponential function using FIG. 3A;

FIG. 3C illustrates the characteristics of the VGA circuitry of FIG. 3B;

FIG. 4 illustrates a VGA circuitry combined with an operational amplifier;

FIG. 5 illustrates a VGA circuitry for differential signals according to the present invention;

FIG. 6 illustrates a VGA circuitry for differential signals, in which a fixed resistor of the VGA circuitry of FIG. 5 is replaced by a MOSFET operating in a saturation region;

FIG. 7 illustrates two or more in serial-combined VGA circuitries having a pseudo exponential function and the equivalent model symbol; and

FIGS. 8A through 8D illustrate the VGA circuitry having a pseudo exponential function according to another embodiment of the present invention.

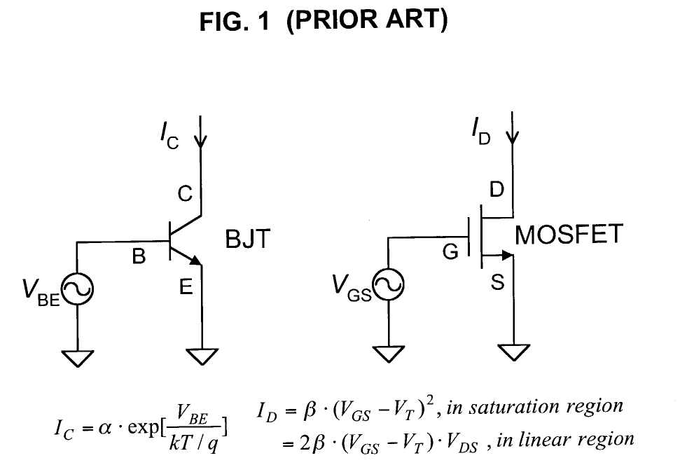

### DETAILED DESCRIPTION OF THE INVENTION

Hereinafter, the present invention will be described in detail by describing preferred embodiments of the invention with reference to the accompanying drawings.

In the presence of describing embodiments of the present invention, the following Equation 3 is an approximate formula for converting a fractional function into an exponential function when the value of x is less than 0.7. However, in consideration of facility of a simple circuitry structure, in Equation 3, x of numerator (1−x) is removed, and 1/(1+x) is approximate similarly to an exponential function.

$$\frac{1 - x}{1 + x} ≅ exp ( - 2 x ) , where x << 1 \qquad ( 3 )$$

Further, in the present invention, a MOSFET operating in a linear region is used as a variable resistor, and the value of variable resistance is obtained by using Equation 4.

$$r = \frac{\partial {V}_{DS}}{\partial {I}_{D}} = \frac{1}{2 β ( {V}_{ct} - {V}_{T} )} \qquad ( 4 )$$

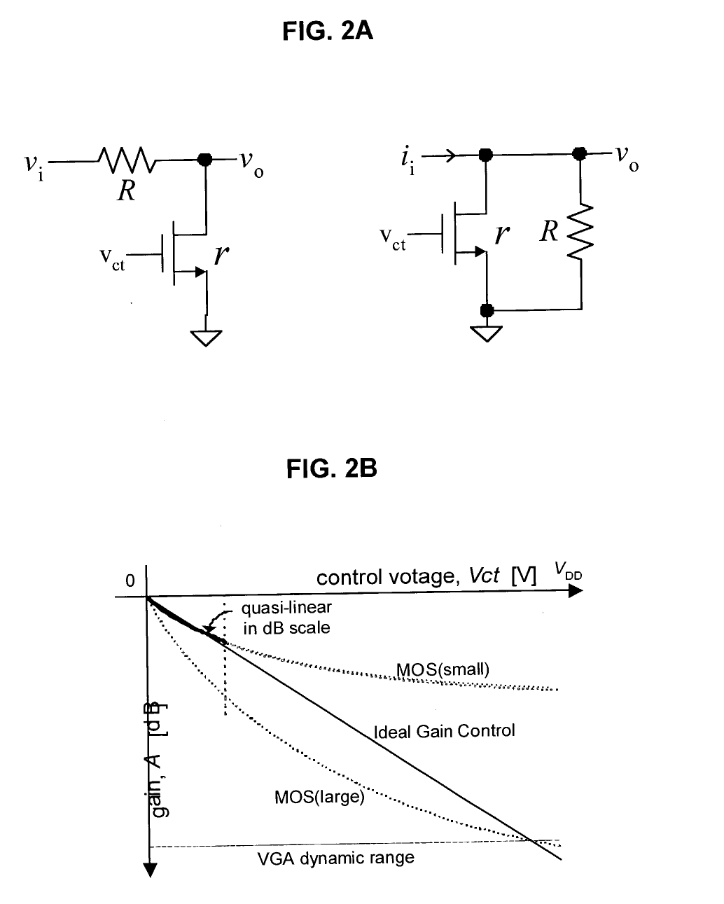

FIG. 2A illustrates a variable gain controller comprised of a fixed resistor and a variable resistor, and FIG. 2B illustrates the characteristics of variable gain A of FIG. 2A. The variable gain controller shown in FIG. 2A is a circuitry having the simplest structure in which gain is varied according to a control voltage V_{ct}. Two circuitries shown in FIG. 2A are constituted depending on whether an input signal is a voltage source or current source in output of a voltage and have equivalent expression, and thus will be described together with the following descriptions of the present invention.

The variable gain A of FIG. 2A is expressed to a pseudo exponential function as Equation 5 by using Equations 3 and 4, and thus we obtain the desired variable gain A which is exponential-functionally varied, by adjusting a fixed resistor R and the size_of the MOSFET properly.

$$\begin{matrix}A = ( \frac{{V}_{o}}{{V}_{i}} or \frac{{V}_{o}}{{i}_{i} \cdot R} ) = \frac{r}{R + r} = \frac{1}{1 + R \cdot 2 β ( {V}_{ct} - {V}_{T} )} \\ ≅ exp ( - 4 β R \cdot ( {V}_{ct} - {V}_{T} ) ) , where 2 β R \cdot ( {V}_{ct} - {V}_{T} ) << 1\end{matrix} \qquad ( 5 )$$

However, as shown in the graph illustrating the characteristics of the variable gain A of FIG. 2B, since the interval having ideal linear decibel (dB) is only a part of the total dynamic range due to limitations caused by approximation of a fractional function to an exponential function, the interval itself cannot put into practice. Thus, the fixed resistor R and the size_of the MOSFET having larger values should be used so as to obtain the total dynamic range. In this case, however, the gain variation differs greatly from the ideal linear decibel (dB).

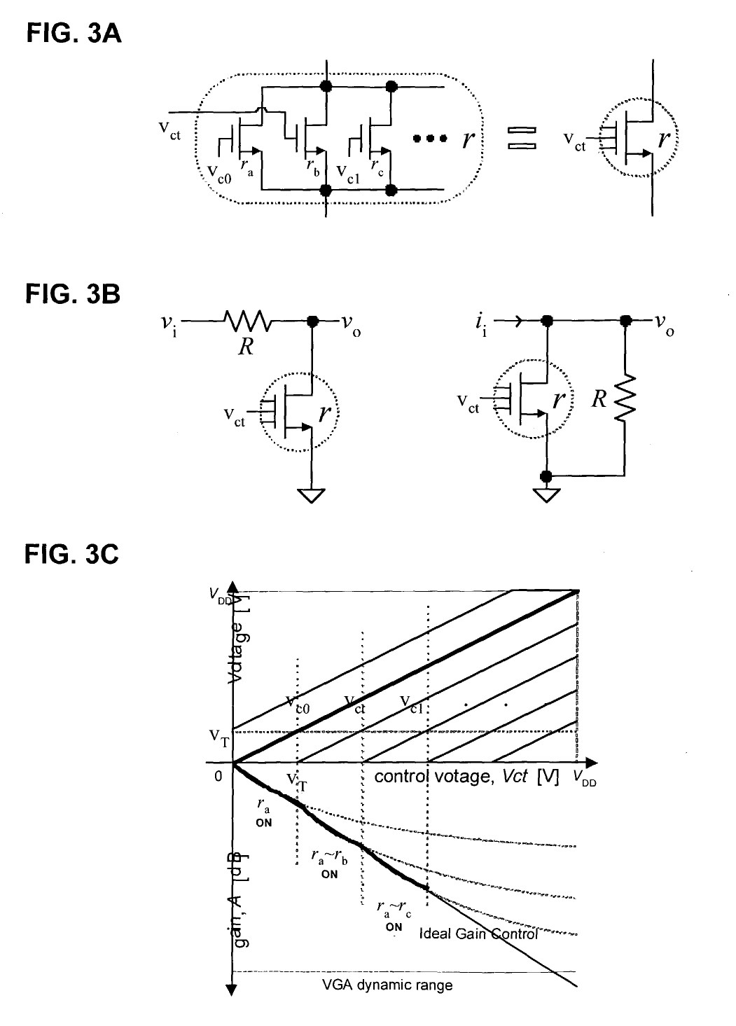

FIG. 3A illustrates a variable resistor according to an embodiment of the present invention and an equivalent symbol model thereof, FIG. 3B illustrates VGA circuitries for generating a pseudo exponential function having the total dynamic range according to an embodiment of the present invention, and FIG. 3C illustrates control voltages V_{c0}, V_{ct}, V_{c1}, . . . , which are input into each transistor, and the gain A variation of the VGA circuitry. The equivalent model of FIG. 3A is used in the following descriptions without additional explanation.

In the present invention, as shown in FIG. 3A, the fixed resistor r of FIGS. 2A and 2B is constituted such that a plurality of MOSFETs operating in a linear region are connected in parallel, the control voltages V_{c0}, V_{ct}, V_{c1}, . . . are applied to the plurality of MOSFETs, respectively, and the in-parallel connected MOSFETs are turned off or on additionally, thereby implementing VGA circuitries shown in FIG. 3B for generating a pseudo exponential function. The control voltages V_{c0}, V_{ct}, V_{c1}, . . . , which are input into gates of the in-parallel connected MOSFETs, respectively. FIGS. 3A through 3C show an example in case that the difference of the control voltages is the same as the threshold voltage V_{T} of the MOSFETs. For simplicity of peripheral circuits of an integrated circuit (IC), it is essential that only the control voltage V_{ct} is applied externally and the other control voltages V_{c0}, V_{c1}, . . . are constituted internally on the basis of the control voltage V_{ct}.

When the externally applied control voltage V_{ct} increases from 0, only the control voltage V_{c0} among the internally generated control voltages V_{c0}, V_{c1}, . . . exceeds the threshold voltage V_{T} of the MOSFETs, and thus only a transistor rₐ among the plurality of linear MOSFETs for constituting the fixed resistor R is maintained in a conductive state. When the control voltage V_{ct} reaches the threshold voltage V_{T} of the MOSFETs, a transistor r_{b} as well as the transistor rₐ in a conductive state is conductive, and thus an equivalent variable resistor r decreases more, and variable gain A is varied according to the locus of a pseudo exponential function by using Equation 5. When the control voltage V_{ct} increases more and reaches a multiple of the threshold voltage V_{T} of the MOSFETs, a transistor r_{c} as well as the transistors rₐ and r_{b} in a conductive state is conductive, and thus the equivalent variable resistor r decreases still more, and the control voltage V_{ct} increases continuously, the plurality of linear MOSFETs are conductive additionally, and the variable gain A follows the locus of variation in ideal variable gain, as shown in FIG. 3C.

When the variable resistor r is implemented in this way, each of the MOSFETs are conductive or nonconductive additionally, and thus the entire linear decibel (dB) to the total dynamic range can be obtained according to the variation in the control voltage V_{ct}. As a result, the variable gain A in the embodiment can be represented as an approximate pseudo exponential function having a value smaller than 1 in the total dynamic range, as shown in Equation 6.

$$A = ( \frac{{V}_{0}}{{V}_{i}} or \frac{{V}_{0}}{{i}_{i} \cdot R} ) ≅ exp ( - 4 βR \cdot ( {V}_{ct} - {V}_{T} ) ) \qquad ( 6 )$$

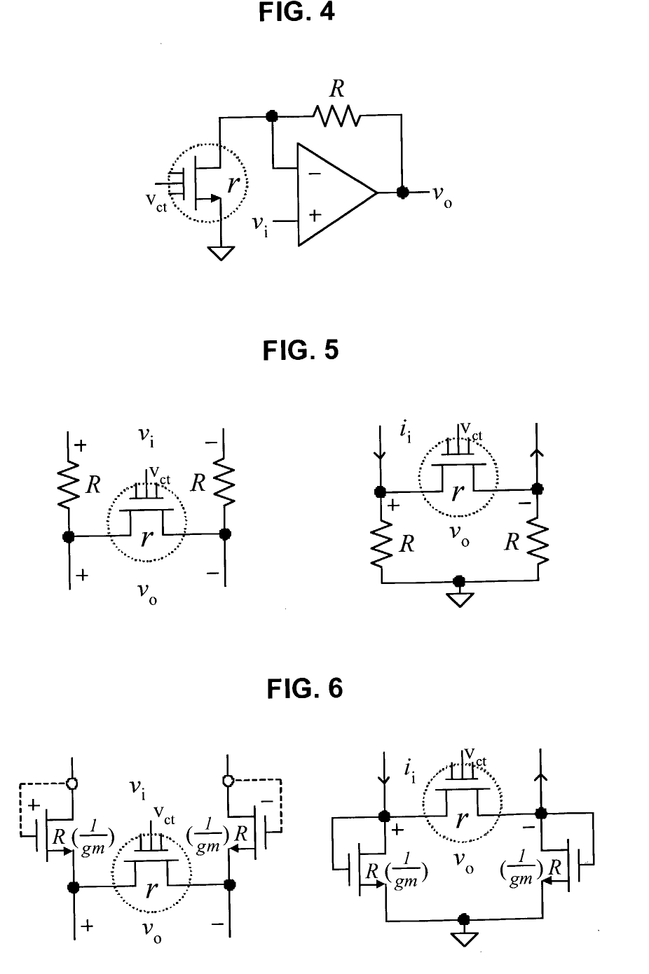

FIG. 4 illustrates a VGA circuitry combined with an operational amplifier, and the VGA circuitry generates gain having the shape of a pseudo exponential function. Since the VGA circuitry shown in FIG. 4 uses error-amplification of the operational amplifier, the variable gain A is always larger than 1, and the VGA circuitry is expressed by Equation 7 in the total dynamic range, in which the order of denominator and numerator of Equation 6 expressing the VGA circuitry shown in FIG. 3B is changed.

$$A = \frac{{V}_{o}}{{V}_{i}} = \frac{R + r}{r} ≅ exp ( 4 β R \cdot ( {V}_{ct} - {V}_{T} ) ) \qquad ( 7 )$$

It is evident that the linear MOSFET used as a variable resistor may be an NMOSFET or PMOSFET and is not limited to one shape.

In general, basic signals in the IC are differential signals. Thus, the following descriptions will be made on the basis of differential signals, and the conversion of the VGA circuitry for differential signals into the VGA circuitry for single signals can be performed by a person skilled in electronic circuits, and thus should be included in the scope of the present invention.

FIG. 5 illustrates VGA circuitries in which each VGA circuitry of FIG. 3B can be applied to differential signals. When the VGA circuitry is divided on the basis of a longitudinal axis at the center, the VGA circuitry is equalized to each circuit shown in FIG. 3B.

FIG. 6 illustrates a circuitry for generating a pseudo exponential function according to another embodiment of the present invention and illustrates a VGA circuitry for differential signals, in which a fixed resistor of the VGA circuitry of FIG. 5 is replaced by a MOSFET operating in a saturation region.

The MOSFET operating in a saturation region is a dependent current source generating an output current proportional to an input voltage, and the equivalent resistance at the source of the MOSFET is expressed as its transconductance (gm) by Equation 8 and has a nearly stable value in steady states.

$$gm = \frac{\partial {I}_{D}}{\partial {V}_{GS}} = 2 β \cdot ( {V}_{Gs} - {V}_{T} ) = 2 \cdot \sqrt{B \cdot {I}_{D}} = \frac{1}{R} \qquad ( 8 )$$

Even though the fixed resistor of FIG. 5 is substituted by the MOSFET operating in a saturation region as shown in FIG. 6, the VGA circuitry performs the same operation as that of FIG. 5. When an input voltage is applied to a gate in FIG. 6, it doesn't matter if a drain is connected to a gate or power supply, and thus this operation is shown using a dotted line.

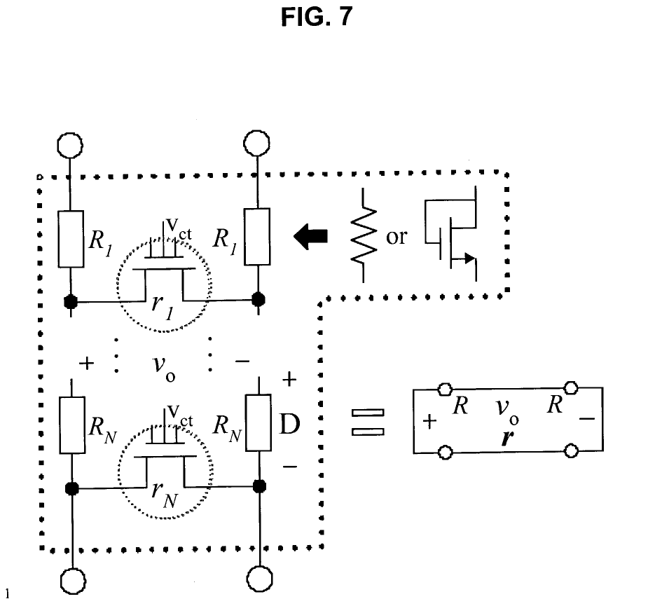

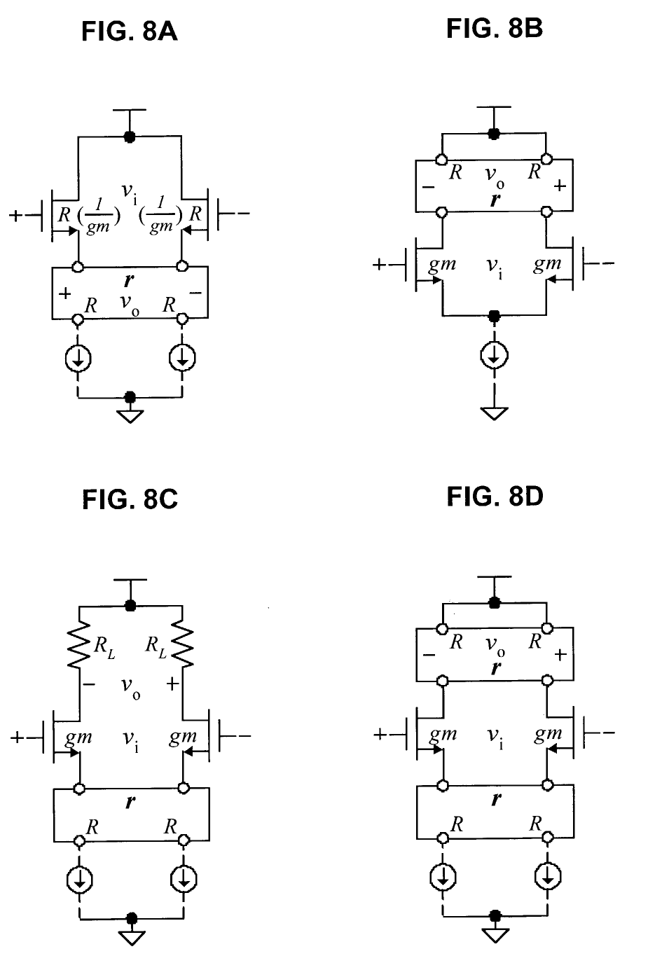

FIG. 7 illustrates a composite circuitry by in serial connecting the circuitries of FIG. 5 or 6 so as to increase the dynamic range, and also shows an equivalent symbol model for simplification of application circuitries shown in FIG. 8. FIG. 7 has a pseudo exponential function with the larger dynamic range according to another embodiment of the present invention, and an arbitrary dot at each terminal can be used as an output voltage. When DC flows through fixed resistors R₁ through R_{N} and voltage drop occurs at both ends of each fixed resistors, only a control voltage V_{ct} can be used in the VGA circuitry to generate a pseudo exponential function shown in FIG. 3 without forming several control voltages. This is like there is a voltage drop in each of variable resistors r₁ through r_{N}, and thus each of the variable resistors r₁ through r_{N} is turned on or off additionally according to the control voltage V_{ct} variation.

FIG. 8 illustrates various application circuitries for generating a pseudo exponential function according to another embodiment of the VGA circuitry using FIG. 7. Even though a current source connected by a dotted line in FIG. 8 is shorted, the applications of the present invention are also possible. In FIG. 8A, only variable gain of attenuation can be obtained by the combination of FIGS. 6 and 7. FIG. 8B uses FIG. 7 as a load of a VGA circuitry for differential signals. For the convenience of equation and description, a case where FIG. 5 having the same section as a section of FIG. 7 is used as load of the VGA circuitry for differential signals is expressed by Equation 9 using Equation 5. Amplification and attenuation of the variable gain A of FIG. 8B are possible as shown in Equation 9, and maximum amplification gain is the same as gm×R.

$$A = \frac{{V}_{o}}{{V}_{i}} = gm \cdot ( R ‖ r ) ≅ gm \cdot R \cdot exp ( - 4 β R \cdot ( {V}_{ct} - {V}_{T} ) ) \qquad ( 9 )$$

FIGS. 8C and 8D use the structure of FIG. 7 as source degeneration and illustrate a circuitry for implementing the variable gain A of amplification and attenuation as a pseudo exponential function by using a fixed resistor R_{L} as load in FIG. 8C and by using FIG. 7 as load in FIG. 8D. It is evident that various application circuitries of FIG. 8 are connected in serial to one another in order to obtain the scope of the larger variable gain as well as the variable gain itself.

As described above, according to the present invention, a VGA circuitry for implementing gain as a pseudo exponential function by using an equivalent variable resistor, which is implemented by combining one or more MOSFETs operating in a linear area and having different control voltages to each of the MOSFETs, can be provided. Although the MOSFET has no exponential characteristics, the VGA circuitry can easily implement a pseudo exponential function with a simple structure. Further, since a complex circuit for generating an

We claim:

1. A variable gain amplifier (VGA) circuitry comprising:
at least one fixed resistor which is composed of either a passive resistor (R) or a metal oxide semiconductor field effect transistor (MOSFET) having the equivalent resistance value (1/gm) at the source node, and one fixed resistor is used for a single signal or two and more fixed resistor are used for differential signal; and
a variable resistor, which is connected in serial to the fixed resistor, composed of a plurality of MOSFETs which are connected in parallel with each other, operate in a linear region, and have the different control voltages at each gate node.

2. The circuitry of claim 1, wherein two or more VGA circuitries are connected in serial in order to obtain larger dynamic range, and the variable resistor in the VGA circuitries uses at least one linear MOSFET having different control voltage with other VGA circuitries.

3. The circuitry of claim 2, wherein only a control voltage is utilized for the VGA circuitries by using the inherent DC voltage drop between the VGA circuitries as the difference of the control voltages.

4. A variable gain amplifier (VGA) circuitry comprising:
at least one fixed resistor which is composed of either a passive resistor (R) or a metal oxide semiconductor field effect transistor (MOSFET) having the equivalent resistance value (1/gm) at the source node, and one fixed resistor is used for a single signal or two and more fixed resistor are used for differential signal; and
a variable resistor, which is connected in serial to the fixed resistor, composed of a plurality of MOSFETs which are connected in parallel with each other, operate in a linear region, and have the different control voltages at each gate node; and
an operational amplifier, which uses the variable resistor and the fixed resistor as an input element and a feedback element, respectively.

5. The circuitry of claim 4, wherein two or more VGA circuitries are connected in serial in order to obtain larger dynamic range, and the variable resistor in the VGA circuitries uses at least one linear MOSFET having different control voltage with other VGA circuitries.

6. The circuitry of claim 5, wherein only a control voltage is utilized for the VGA circuitries by using the inherent dc voltage drop between the VGA circuitries as the difference of the control voltages.

7. A variable gain amplifier (VGA) circuitry comprising:
at least one fixed resistor which is composed of either a passive resistor (R) or a metal oxide semiconductor field effect transistor (MOSFET) having the equivalent resistance value (1/gm) at the source node, and one fixed resistor is used for a single signal or two and more fixed resistor are used for differential signal; and
a variable resistor, which is connected in serial to the fixed resistor, composed of a plurality of MOSFETs which are connected in parallel with each other, operate in a linear region, and have the different control voltages at each gate node; and
at least one MOSFET operating in saturation region for signal amplification, which is one MOSFET is used for single signal or two MOSFETs are used for differential signal, and connected directly with the fixed resistor or the variable resistor at the source or drain node of the saturation MOSFET.

8. The circuitry of claim 7, wherein two or more VGA circuitries are connected in serial in order to obtain larger dynamic range, and the variable resistor in the VGA circuitries uses at least one linear MOSFET having different control voltage with other VGA circuitries.

9. The circuitry of claim 8, wherein only a control voltage is utilized for the VGA circuitries by using the inherent dc voltage drop between the VGA circuitries as the difference of the control voltages.
